(19) United States
(12) Patent Application Publication
(10) Pub. No.: US 2025/0172625 A1
(43) Pub. Date: May 29, 2025

(54) BATTERY TEST APPARATUS AND METHOD

(71) Applicant: SAMSUNG SDI CO., LTD., Yongin-si (KR)

(72) Inventors: Sungsoo KIM, Yongin-si (KR); Jaehyoun LEE, Yongin-si (KR); Byeonghui LIM, Yongin-si (KR); Bora KIM, Yongin-si (KR); Jee Hoon HAN, Yongin-si (KR); Jongman KIM, Yongin-si (KR); Giheon KIM, Yongin-si (KR)

(21) Appl. No.: 18/614,284

(22) Filed: Mar. 22, 2024

(30) Foreign Application Priority Data
Nov. 27, 2023 (KR) 10-2023-0166732

(51) Int. Cl. G01R 31/392; G01R 31/367; G01R 31/3842; H02J 7/00

(52) U.S. Cl. CPC G01R 31/392; G01R 31/367; G01R 31/3842; H02J 7/005

(57) ABSTRACT

A battery testing method may include generating a test pattern in which a cycle includes at least one operation for a test list, and a loop indicating a number of repetitions of the cycle, setting a tag indicating a test type in the at least one operation, testing the battery by charging and discharging the battery according to the test pattern, and storing voltage data and current data in memory as a test result for the test pattern.

### CROSS-REFERENCE TO RELATED APPLICATION

The present application claims priority to and the benefit of Korean Patent Application No. 10-2023-0166732, filed on Nov. 27, 2023, in the Korean Intellectual Property Office, the entire disclosure of which is incorporated herein by reference.

### BACKGROUND

### 1. Field

This disclosure relates to battery test apparatus and method.

### 2. Description of the Related Art

A battery test apparatus may evaluate the electrical characteristics of battery cells by repeatedly charging and discharging of battery cells.

Among the data collected during charging and discharging of battery cells, only some are the meaningful data that are actually used for evaluation, and classification of meaningful data in the data collected may be done manually, which may consume significant time and money.

### SUMMARY

At least one of the embodiments may provide a battery test apparatus, and a method that can suitably extract data from battery test data.

At least one of the embodiments may provide a battery test apparatus, and a method that can suitably extract meaningful data related to battery life from battery test data, and that can perform battery life prediction using the extracted meaningful data.

According to one or more embodiments, a battery test method for testing a battery in a battery test apparatus may be provided. The battery testing method may include generating a test pattern in which a cycle includes at least one operation for a test list, and a loop indicating a number of repetitions of the cycle, setting a tag indicating a test type in the at least one operation, testing the battery by charging and discharging the battery according to the test pattern, and storing voltage data and current data in memory as a test result for the test pattern.

The storing the voltage data and the current data may include tagging information of the tag in the test result.

The test type may correspond to testing an internal resistance of the battery, a capacity of the battery, a temperature of the battery, a life of the battery, a charge and discharge rate of the battery, or a formation of the battery.

The battery test method may further include receiving a life test command of the battery, extracting the current data and the voltage data for the cycle tagged with the information of the tag indicating a life of the battery from the memory, and predicting the life of the battery using the current data and the voltage data.

The predicting the life of the battery may include calculating capacity data for the cycle using the current data, calculating capacity-to-voltage differential characteristic data for the cycle using the capacity data and the voltage data, and predicting the life of the battery from the capacity-to-voltage differential characteristic data using a life prediction model.

The at least one operation may include a charge operation, a rest operation, or a discharge operation, wherein the at least one operation further includes an operation condition and an end condition.

According to one or more other embodiments, a battery test apparatus for testing a battery may be provided. The battery test apparatus may include a storage device, a charge-and-discharge device electrically connected to the battery, and configured to charge and to discharge the battery according to a test pattern including at least one test list that includes a cycle including at least one operation, and a loop indicating a number of repetitions of the cycle, and a controller configured to generate a battery pattern based on user input, to provide the battery pattern to the charge-and-discharge device, to control testing of the battery, to store test result data in the storage device in response to the battery pattern, and to set a tag indicating a test type in the at least one operation.

The controller may be configured to tag information of the tag in test result data, and to store the test result data that is tagged with the information of the tag.

The test type may correspond to testing an internal resistance of the battery, a capacity of the battery, a temperature of the battery, a life of the battery, a charge and discharge rate of the battery, or a formation of the battery.

The controller may be configured to extract the test result data from the storage device, and to evaluate the test type using the test result data.

The controller may be configured to extract the test result data from the storage device based on a battery life test command, and to evaluate a life of the battery using the test result data.

The controller may be configured to evaluate the life of the battery from the test result data using a learned life prediction model.

The at least one operation may include a charge operation, a rest operation, or a discharge operation, wherein the at least one operation further includes an operation condition and an end condition.

### BRIEF DESCRIPTION OF DRAWINGS

FIG. 1 is a diagram showing a battery test apparatus according to one or more other embodiments.

FIG. 2 is a diagram showing an example of a battery according to one or more embodiments.

FIG. 3 is a diagram showing an example of a test pattern according to one or more embodiments.

FIG. 4 is a diagram showing a method of generating a test pattern in the controller shown in FIG. 1.

FIG. 5 is a flowchart showing a method for predicting the life of a battery in a battery test apparatus according to one or more other embodiments.

FIG. 6 is a diagram showing a method of learning a life prediction model according to one or more embodiments.

FIG. 7 is a diagram showing an example of capacity-to-voltage differential characteristic data for each cycle in a learning sample.

FIG. 8 is a diagram showing an example of life data for each cycle in a learning sample.

FIG. 9 is a diagram showing a life prediction apparatus according to one or more other embodiments.

FIG. 10 is a diagram showing a battery test apparatus according to one or more other embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

It will be understood that when an element, layer, region, or component is referred to as being “connected to” or “(operatively or communicatively) coupled to” another element, layer, region, or component, it can be directly connected to or coupled to the other element, layer, region, or component, or indirectly connected to or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection refers to one component directly connecting or coupling another component without an intermediate component. In addition, it will be understood that when an element or layer is referred to as being “between” two elements or layers, it can be the only element or layer between the two elements or layers, or one or more intervening elements or layers may also be present.

For the purposes of this disclosure, expressions, such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions, such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

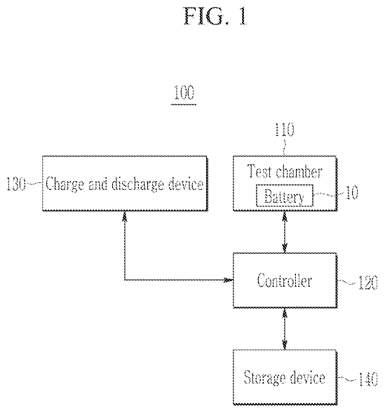

FIG. 1 is a diagram showing a battery test apparatus according to one or more other embodiments.

Referring to FIG. 1, the battery test apparatus 100 may include a test chamber 110, a controller 120, a charge-and-discharge device 130, and a storage device 140.

The test chamber 110 may be configured to accommodate the battery 10 to be tested. Here, the battery 10 may be a battery module including a plurality of battery cells, or may be a battery pack including at least one battery module.

The battery test apparatus 100 may perform a test on the battery 10, while the battery 10 may be mounted in the test chamber 110, and may be connected to the charge-and-discharge device 130 through a communication interface.

The charge-and-discharge device 130 may charge the battery 10 or may discharge the battery 10. The charge-and-discharge device 130 may charge or discharge the battery 10 based on a control signal from the controller 120. At this time, the control signal may include current value, charging rate, and/or discharging rate.

The controller 120 may perform a test on the battery 10 according to a test pattern. The controller 120 may generate the test pattern based on user input.

The test pattern may be commands that arrange the order, operations, and/or conditions for battery charging and discharging testing. The conditions may include test environment information, such as charge rate, discharge rate, charge end condition, discharge end condition, charge mode, discharge mode, and temperature. The operations may include a charging operation, a discharging operation, and a rest operation. As an example, a battery test pattern may be commands in which operations and conditions are sequentially listed, such as charging for about 1 hour with a current of about 1 A, discharging for about 10 seconds with a current of about 10 A, resting for about 30 minutes, and charging for about 1 hour with a current of about 2 A.

The controller 120 may generate control signals to control the charge-and-discharge device 130 according to the test pattern, and may transmit the control signals to the charge-and-discharge device 130.

The controller 120 may test the battery 10 in response to the test pattern, and may measure or collect data corresponding to the test result. The controller 120 may store data corresponding to test results in the storage device 140.

The controller 120 may display result data corresponding to a test pattern or result data corresponding to a specific operation selected by the user. The controller 120 may display the result data in a graph according to the settings input by the user.

The controller 120 may calculate other data using the result data corresponding to the test pattern, and may store and manage calculated other data. For example, the controller 120 may calculate capacity data by integrating current data.

The controller 120 may evaluate the performance of the battery 10 using data stored in the storage device 140. The controller 120 may extract meaningful data depending on the type of test (e.g., performance evaluation) from the data stored in the storage device 140, and may evaluate performance using the extracted data.

In one or more other embodiments, the controller 120 may generate the test pattern using tags to suitably extract meaningful data depending on the type of performance evaluation. For example, the controller 120 may use tags to indicate which operations in the test pattern are used for which performance evaluation. If a tag is set in a certain operation, the test result data corresponding to the operation may be tagged and stored with the corresponding tag information. In this way, the controller 120 may suitably extract meaningful data for the performance evaluation using the tag information.

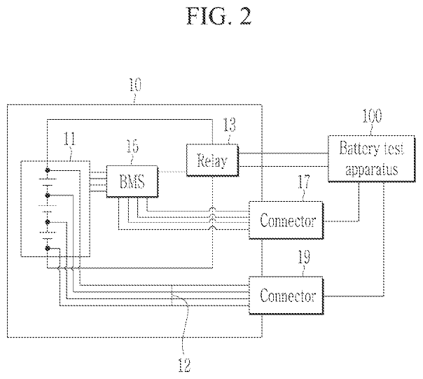

FIG. 2 is a diagram showing an example of a battery according to one or more embodiments.

Referring to FIG. 2, the battery 10 may include at least one battery module 11, a relay 13, and a battery management system (BMS) 15.

The battery 10 may be connected to the charge-and-discharge device (130 in FIG. 1) through the relay 13, and may be charged or discharged by the charge-and-discharge device (130 in FIG. 1).

The battery module 11 may include a plurality of cells electrically connected to each other in series and/or parallel.

The relay 13 may control the electrical connection between the battery module 11 and an external device. According to one or more other embodiments, the external device may be a charger/discharger (e.g., change-and-discharge device 130 in FIG. 1). If the relay 13 is turned on, the battery module 11 and the charge-and-discharge device 130 may be electrically connected so that charging or discharging may be performed, and if the relay 13 is turned off, the battery module 11 and charge-and-discharge device 130 may be electrically separated.

The BMS 15 may control and manage the overall operation of the battery 10. The BMS 15 may monitor the overall status of the battery module 11 and the cells included in the battery module 11. The BMS 15 may perform various control functions to adjust the state of the battery module 11 and the cells included in the battery module 11. For example, the BMS 15 may be electrically connected to a positive electrode and a negative electrode of each of a plurality of cells to measure or collect cell voltage. As another example, BMS 15 may measure or collect battery current and temperature. The BMS 15 may control the charge current and/or discharge current of the battery module 11 based on information, such as cell voltage of the plurality of cells, battery current, and battery temperature, and may perform a cell-balancing operation for the plurality of cells. The BMS 15 may control the switching of the relay 13 to charge or discharge the battery module 11.

A connector 17 may be a connection device for connecting the BMS 15 and the battery test apparatus 100. The BMS 15 may provide measured data to the battery test apparatus 100 through the connector 17.

Another connector 19 may be a connection device for connecting the battery module 11 and the battery test apparatus 100. For example, the connector 19 may connect the battery test apparatus 100 with a plurality of lines 12 electrically connected to the positive electrode and to the negative electrode of each of the plurality of cells.

Accordingly, the battery test apparatus 100 may measure the voltage of each cell, or may collect the voltage of each cell.

According to one or more other embodiments, the battery test apparatus 100 may test the battery 10 by controlling the BMS 15 according to the test pattern, and the BMS 15 may measure cell voltage, battery current, and temperature, etc., and may provide the measured data to the battery test apparatus 100. The test pattern may be a kind of test scenario for testing.

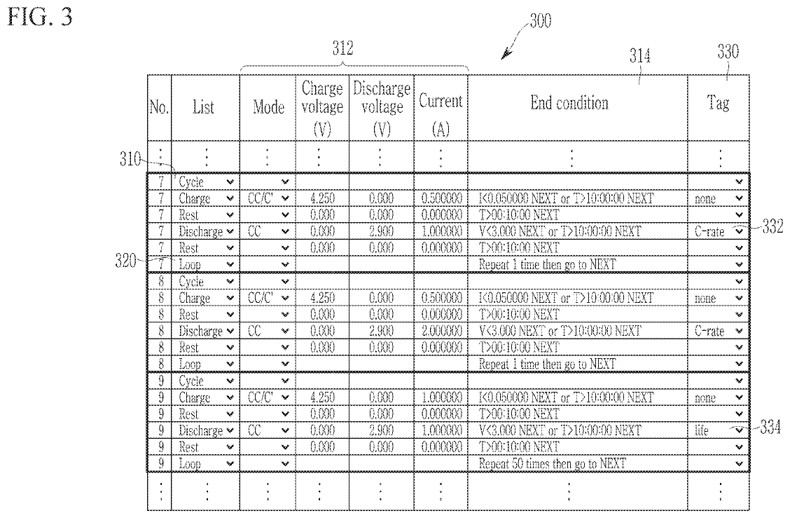

FIG. 3 is a diagram showing an example of a test pattern according to one or more embodiments.

Referring to FIG. 3, the battery test apparatus 100 may generate a test pattern 300 according to the test object and the type of test, or test type, to be tested for the test object.

In one or more other embodiments, the test object may be a battery 10. The type of test may be a characteristic item of the battery 10 to be tested, for example, it may include internal resistance of the battery 10, capacity of the battery 10, temperature of the battery 10, life of the battery 10, charge rate of the battery 10, discharge rate of the battery 10, the formation of the battery 10, etc.

The test pattern 300 may include a plurality of test lists. In FIG. 3, for convenience of explanation, only a 7-th test list, an 8-th test list, and a 9-th test list for one test object are shown.

Each test list may include cycles 310 and loops 320 representing test items. Each test list may further include a tag 330.

Each cycle may include a series of operations performed in the corresponding test list, and each operation may include an operation condition 312 and an end condition 314. The operation condition 312 may represent test conditions for the corresponding operation and may include mode information, charge voltage, discharge voltage, and current.

As an example, the cycle in the 7-th test list may include the operations of a charge operation, a rest operation, a discharge operation, and (another) rest operation. Additionally, the operating condition of the charge operation may include at least one of mode information, charge voltage, discharge voltage, and current. The mode information may indicate the type of charging or discharging. For example, the mode information may include at least one of constant current (CC) charge/discharge method, constant voltage (CV) charge/discharge method, CC and CV combination charge method, constant power (CP) charge/discharge method, and constant resistance (CR) discharge method. The unit of charge voltage and discharge voltage may be volts (V), and the unit of current may be amperes (A).

In FIG. 3, for convenience, the cycles of the 7-th test list, the 8-th test list, and the 9-th test list are all shown as operations of a charge operation, a rest operation, a discharge operation, and (another) rest operation, but the cycles in each test list may be set differently. For example, a cycle of any one test list may include only the operations of charge operation and rest operation. This may be determined based on user input.

The loop 320 may represent the number of repetitions of the cycle. The loop 320 may include a loop end condition. If “repeat 1 time” is set as the loop end condition, the loop may be set to 1, and after performing one cycle, the test operations in the next test list may be performed.

As an example, the cycle 310 of the 7-th test list may include operations of a charge operation, a rest operation, a discharge operation, and (another) rest operation, the charge operation may include operation conditions of “a charge voltage of 4.25V, a current of 0.5 A, and CC/CV mode,” and the discharge operation may include operation conditions of “discharge voltage of 2.9V, current of 1 A, and CC mode.” Each operation may further include an end condition. The end condition of the charge operation may include “I<0.050000 NEXT” or “T>10:00:00 NEXT,” the end condition of the rest operation may include “T>00:10:00 NEXT,” and the end condition of the discharge operation may include “V<3.000 NEXT” or “T>10:00:00 NEXT.” In 7-th test list, the loop end condition of the loop may include “repeat 1 time then go to NEXT.” In the charge operation, the operation condition of “charge voltage of 4.25V, current of 0.5 A, and CC/CV mode” may indicate charging of the battery in “charge voltage of 4.25V, current of 0.5 A, and CC/CV mode.” In the discharge operation, the operation condition of “discharge voltage of 2.9V, current of 1 A, and CC mode” may indicate discharging of the battery 10 in “discharge voltage of 2.9V, current of 1 A, and CC mode.” The end condition “T>10:00:00 NEXT” in the charge operation may indicate that if 10 hours have passed after the start of charging, then end the charge operation and go to the rest operation, which is the next operation. In addition, “I<0.050000 NEXT” may indicate that if the current I of the battery 10 is less than 0.05 A, then end the charge operation and go to the rest operation, which is the next operation. The end condition in the discharge operation, “V<3.000 NEXT” may indicate that if the battery voltage V is less than 3V in the discharge operation, then end the discharge operation and go to the rest operation, which is the next operation.

According to one or more other embodiments, the controller 120 of the battery test apparatus 100 may set the tag 330 to an operation (e.g., predetermined operation) in the test list according to the characteristic item of the battery 10 to be tested based on user input.

The controller 120 may test the battery 10 corresponding to the operations of each cycle in each test list, and may store the data measured in each operation in response to each operation. At this time, if the tag 330 is set in one operation, in the controller 120, the data measured in the corresponding operation may be tagged and stored with the corresponding tag information.

As an example, in cycle 310 of the 7-th test list, if the tag 332 of “C-rate” is set in the discharge operation, the controller 120 may discharge the battery 10 according to the discharge operation of the cycle 310 of the 7-th test list, may tag the measured current and the voltage data with tag information of “C-rate,” and may store current and voltage data tagged with tag information. The tag “C-rate” may indicate the characteristic item of charge and discharge rate.

As another example, the cycle of the 9-th test list may include operations of a charge operation, a rest operation, a discharge operation, and (another) rest operation, and the charge operation may include the operation conditions of a charge voltage of 4.25V, a current of 1 A, and operation in a CC/CV mode. The discharge operation may include the operation conditions of a discharge voltage of 2.9V, a current of 1 A, and operation in a CC mode. Each operation may further include an end condition. The end condition of the charge operation may include “I<0.050000 NEXT” or “T>10:00:00 NEXT,” and the end condition of the rest operation may include “T>00:10:00 NEXT,” and the end condition of the discharge operation may include “V<3.000 NEXT” or “T>10:00:00 NEXT.” In the 9-th test list, the loop end condition of the loop may include “repeat 50 times then go to NEXT.” That is, after repeating the operation of the cycle 50 times, the next operation in the test list may be performed. At this time, the controller 120 may set a tag 334 called “life” in the discharge operation of the cycle. Here, the tag “life” may represent a characteristic item of life (e.g., a lifespan of the battery).

The controller 120 may test the battery 10 according to 50 cycles, in the 9-th test list, and may store data measured in each operation of each cycle in response to each operation of each cycle. At this time, the data measured in each discharge operation of each cycle may be tagged and stored with the tag information “life.”

In this way, after the test of the battery 10 according to the test pattern is completed, the controller 120 may extract only data measured in 50 discharge operations of the 9-th test list using the tag information “life” among the data stored in the storage device 140.

In this way, the tag according to one or more embodiments may be used to suitably extract result data corresponding to a certain test command after test commands are executed.

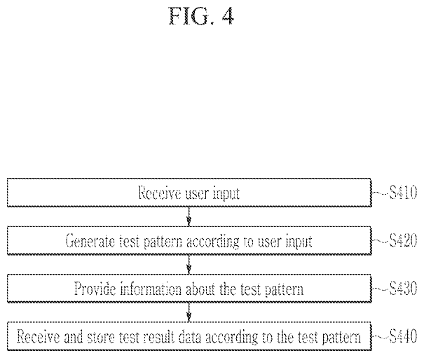

FIG. 4 is a diagram showing a method of generating a test pattern in the controller shown in FIG. 1.

Referring to FIG. 4, the controller 120 may receive user input for testing (S410).

The controller 120 may generate a test pattern according to user input (S420). The controller 120 may generate a test pattern as shown in FIG. 3 based on user input. The user input may include information about the cycle of each test list, information about the presence of a tag, tag type information, end condition information of the test list, operation conditions and end conditions of each operation of the cycle, etc.

The controller 120 may provide information about the test pattern to the charge-and-discharge device 130 (S430), and may control the battery 10 according to the test pattern.

The charge-and-discharge device 130 may charge or discharge the battery 10 based on the test pattern.

The controller 120 may receive test result data according to charging and discharging of the battery 10 based on the test pattern, and may store the test result data according to the test pattern in the storage device 140 (S440). The test result data may include, for example, current data of the battery, voltage data of the battery, and temperature data.

The controller 120 may check whether each operation has a tag, and if there is an action operation in which the tag is set, the controller 120 may tag and store the corresponding tag information to the test result data according to the operation in which the tag is set.

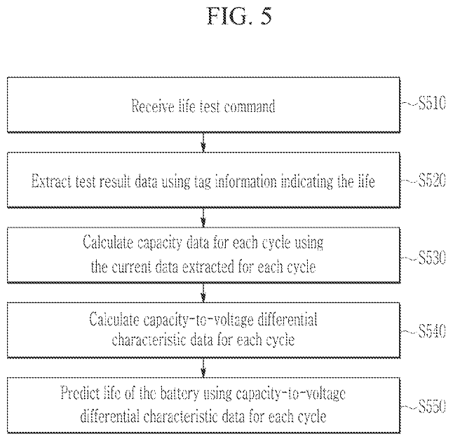

Below, one or more other embodiments of predicting the life/lifespan of a battery using data extracted from a battery test apparatus will be described with reference to FIGS. 5 to 9.

FIG. 5 is a flowchart showing a method for predicting the life of a battery in a battery test apparatus according to one or more other embodiments.

Referring to FIG. 5, the controller 120 of the battery test apparatus 100 may receive a life test command (e.g., lifespan test command) from the user (S510).

First, it is assumed that a test operation of the battery 10 was performed according to the battery test method shown in FIG. 4, and test result data according to the test pattern was stored in the storage device 140.

The controller 120 may extract test result data using tag information of “life” indicating the life of the battery from the storage device 140 based on the life test command (S520). The controller 120 may extract test result data tagged with tag information of “life” indicating life from the storage device 140. As an example, if the battery 10 is tested according to the test pattern 300 shown in FIG. 3, the result data tested according to the 50 discharge operations among operations of the 9-th test list may be tagged with tag information of “life,” and may store the result data tagged with the tag information of “life,” and the result data tested according to the 50 discharge operations may be extracted using the tag information of “life.”

The controller 120 may calculate capacity data for each cycle using the current data extracted for each cycle (S530), and may calculate capacity-to-voltage differential characteristic data for each cycle by differentiating the capacity data for each cycle into voltage data (S540).

The controller 120 may predict the life of the battery 10 using capacity-to-voltage differential characteristic data for each cycle (S550).

According to one or more other embodiments, the battery test apparatus 100 may predict the life of the battery 10 using a life prediction model. The life prediction model may be a learned model. The battery test apparatus 100 may input capacity-to-voltage differential characteristic data for each cycle into the life prediction model. The lifespan prediction model may output a life prediction result of the battery 10 predicted from capacity-to-voltage differential characteristic data for each cycle. As one example, the life prediction model may predict that the remaining life of the battery 10 is “long” or “short.” As another example, the life prediction model may predict the remaining life of the battery 10 as an approximate number of months.

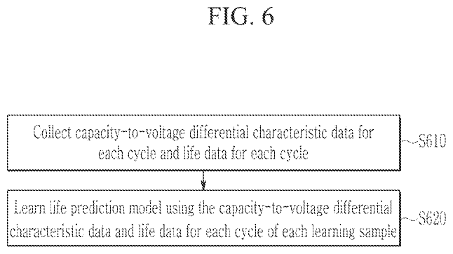

FIG. 6 is a diagram showing a method of learning a life prediction model according to one or more embodiments.

Referring to FIG. 6, the learning device may collect learning data (S610). The learning data may include capacity-to-voltage differential characteristic data and life data for each cycle of each learning sample. Here, the learning sample may be a battery. The learning device may be a separate device, and the function of the learning device may be implemented in the controller 120.

A test of the battery may be performed on the learning samples according to the test pattern shown in FIG. 3, and current and voltage data may be extracted among the test result data using tag information of “life” indicating life evaluation.

The capacity-to-voltage differential characteristic data for each cycle of the learning samples may be calculated using current and voltage data extracted using the tag information of “life” for the learning samples, and capacity data for each cycle may be calculated as life data for each cycle of the learning samples.

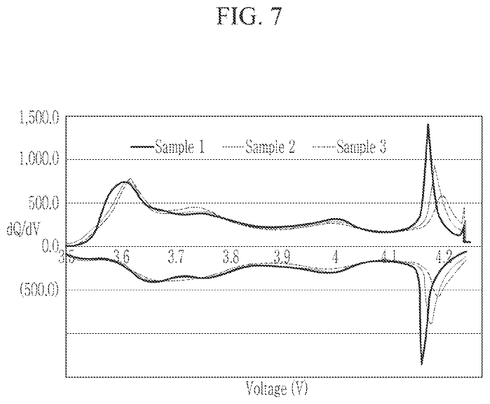

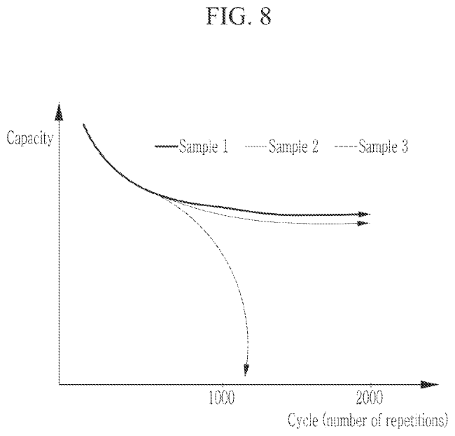

FIG. 7 is a diagram showing an example of capacity-to-voltage differential characteristic data for each cycle in a learning sample, and FIG. 8 is a diagram showing an example of life data for each cycle in a learning sample.

Although only three samples are shown in FIGS. 7 and 8, the number of learning data may be sufficient to train a life prediction model, and the prediction accuracy of the life prediction model may increase as the amount of training data increases.

Referring back to FIG. 6, the learning device may learn the life prediction model using the capacity-to-voltage differential characteristic data and life data for each cycle of each learning sample (S620). The life prediction model may learn the correlation between the voltage range in which capacity decreases, and may learn the life deterioration tendency according to each cycle, using the capacity-to-voltage differential characteristic data and the life data for each cycle of each learning sample, and may predict and classify a long-life battery and a short-life battery.

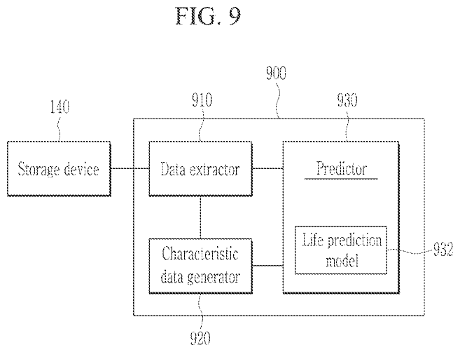

FIG. 9 is a diagram showing a life prediction apparatus according to one or more other embodiments.

Referring to FIG. 9, the life prediction apparatus 900 may include a data extractor 910, a characteristic data generator 920, and a predictor 930. The life prediction apparatus 900 may be implemented within the battery test apparatus 100, and may be a separate and independent device from the battery test apparatus.

The data extractor 910 may extract current and voltage data corresponding to test result data from the storage device 140 based on the life evaluation command using tag information of “life” indicating the life evaluation.

The characteristic data generator 920 may calculate capacity data for each cycle using current data extracted for each cycle, and may calculate capacity-to-voltage differential characteristic data for each cycle by differentiating the capacity data for each cycle into voltage data for each cycle.

The predictor 930 may include a life prediction model 932. The predictor 930 may input capacity-to-voltage differential characteristic data for each cycle into the life prediction model 932. The life prediction model 932 may receive capacity-to-voltage differential characteristic data for each cycle as input, and may output a life prediction result corresponding to the capacity-to-voltage differential characteristic data for each cycle.

In this way, using the life prediction model 932, life prediction results may be output even with a small amount of data. For example, the life prediction model 932 may be learned using data obtained from the entire life of 500 cycles, but if predicting the life of the battery that is the target of prediction using the learned life prediction model 932, accurate life prediction results may be obtained even if only data obtained from 200 cycles are used.

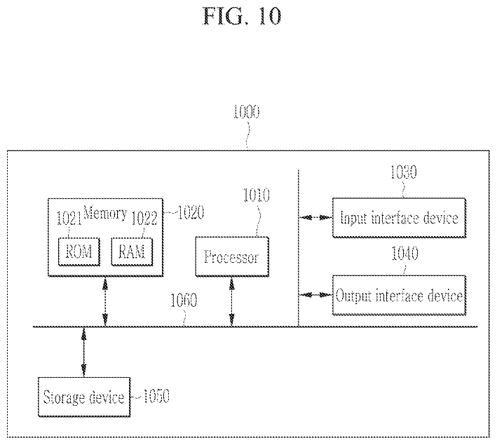

FIG. 10 is a diagram showing a battery test apparatus according to one or more other embodiments.

Referring to FIG. 10, the battery test apparatus 1000 may represent a computing device that implements the battery test method and/or the method for predicting the life of a test battery described above.

The battery test apparatus 1000 may include at least one of a processor 1010, a memory 1020, an input interface device 1030, an output interface device 1040, and a storage device 1050. Each component may be connected by a bus 1060 and may communicate with each other. Additionally, each component may be connected through an individual interface or individual bus centered on the processor 1010, rather than the common bus 1060.

The processor 1010 may be implemented as various types, such as an application processor (AP), a central processing unit (CPU), a graphics processing unit (GPU), etc., and may be any semiconductor device that executes a command stored in the memory 1020 or storage device 1050. The processor 1010 may execute program commands stored in at least one of the memory 1020 and the storage device 1050. This processor 1010 may be configured to implement the functions and methods described based on FIGS. 1 to 9 above.

The memory 1020 and storage device 1050 may include various types of volatile or non-volatile storage media. For example, the memory 1020 may include read-only memory (ROM) 1021 and random access memory (RAM) 1022. In one or more other embodiments, the memory 1020 may be located inside or outside the processor 1010, and the memory 1020 may be connected to the processor 1010 through various known means.

The input interface device 1030 may be configured to provide data to the processor 1010.

The output interface device 1040 may be configured to output data from the processor 1010.

According to at least one of the embodiments, data to be extracted may be suitably extracted using tag information.

Although the embodiments of the present disclosure have been described in detail above, the scope of the present disclosure is not limited thereto, and various modifications and improvements of those skilled in the art using the basic concepts of the present disclosure defined in the following claims, with functional equivalents thereof to be included therein, are also included in the present disclosure.

### DESCRIPTION OF SOME THE REFERENCE CHARACTERS

10: battery 11: battery module
13: relay 15: BMS
17, 19: connector 100: battery test apparatus
110: test chamber 120: controller
130: charge-and-discharge device 140: storage device
900: life prediction apparatus 910: data extractor
920: characteristic data generator 930: predictor
932: life prediction model

What is claimed is:

1. A battery test method for testing a battery in a battery test apparatus, the battery test method comprising:
generating a test pattern in which a cycle comprises:
at least one operation for a test list; and
a loop indicating a number of repetitions of the cycle;
setting a tag indicating a test type in the at least one operation;
testing the battery by charging and discharging the battery according to the test pattern; and
storing voltage data and current data in memory as a test result for the test pattern.

2. The battery test method as claimed in claim 1, wherein the storing the voltage data and the current data comprises tagging information of the tag in the test result.

3. The battery test method as claimed in claim 2, wherein the test type corresponds to testing an internal resistance of the battery, a capacity of the battery, a temperature of the battery, a life of the battery, a charge and discharge rate of the battery, or a formation of the battery.

4. The battery test method as claimed in claim 2, further comprising:
receiving a life test command of the battery;
extracting the current data and the voltage data for the cycle tagged with the information of the tag indicating a life of the battery from the memory; and
predicting the life of the battery using the current data and the voltage data.

5. The battery test method as claimed in claim 4, wherein the predicting the life of the battery comprises:
calculating capacity data for the cycle using the current data;
calculating capacity-to-voltage differential characteristic data for the cycle using the capacity data and the voltage data; and
predicting the life of the battery from the capacity-to-voltage differential characteristic data using a life prediction model.

6. The battery test method as claimed in claim 1, wherein the at least one operation comprises a charge operation, a rest operation, or a discharge operation, and
wherein the at least one operation further comprises an operation condition and an end condition.

7. A battery test apparatus for testing a battery, the battery test apparatus comprising:
a storage device;
a charge-and-discharge device electrically connected to the battery, and configured to charge and to discharge the battery according to a test pattern comprising at least one test list that comprises a cycle comprising at least one operation, and a loop indicating a number of repetitions of the cycle; and
a controller configured to generate a battery pattern based on user input, to provide the battery pattern to the charge-and-discharge device, to control testing of the battery, to store test result data in the storage device in response to the battery pattern, and to set a tag indicating a test type in the at least one operation.

8. The battery test apparatus as claimed in claim 7, wherein the controller is configured to tag information of the tag in test result data, and to store the test result data that is tagged with the information of the tag.

9. The battery test apparatus as claimed in claim 8, wherein the test type corresponds to testing an internal resistance of the battery, a capacity of the battery, a temperature of the battery, a life of the battery, a charge and discharge rate of the battery, or a formation of the battery.

10. The battery test apparatus as claimed in claim 8, wherein the controller is configured to extract the test result data from the storage device, and to evaluate the test type using the test result data.

11. The battery test apparatus as claimed in claim 8, wherein the controller is configured to extract the test result data from the storage device based on a battery life test command, and to evaluate a life of the battery using the test result data.

12. The battery test apparatus as claimed in claim 11, wherein the controller is configured to evaluate the life of the battery from the test result data using a learned life prediction model.

13. The battery test apparatus as claimed in claim 7, wherein the at least one operation comprises a charge operation, a rest operation, or a discharge operation, and
wherein the at least one operation further comprises an operation condition and an end condition.
